(19) United States
(12) Patent Application Publication
(10) Pub. No.: US 2026/0190677 A1
(43) Pub. Date: Jul. 2, 2026

(54) DISPLAY DEVICE

(71) Applicant: Sharp Display Technology Corporation, Kameyama City, Mie (JP)

(72) Inventors: Tadayoshi MIYAMOTO, Kameyama City, Mie (JP); Yoshinobu NAKAMURA, Kameyama City, Mie (JP); Toshihiro KANEKO, Kameyama City, Mie (JP)

(21) Appl. No.: 19/125,554

(22) PCT Filed: Nov. 9, 2022
(86) PCT No.: PCT/JP2022/041709

§ 371 Date: Apr. 29, 2025

(51) Int. Cl. H10K 59/126; H10K 59/12; H10K 59/80

(52) U.S. Cl. CPC H10K 59/126; H10K 59/1201; H10K 59/80518; H10K 59/80524; H10K 59/871

(57) ABSTRACT

In a light-emitting element layer provided on a TFT layer, a plurality of first electrodes, a first edge cover provided in common, a plurality of light-emitting function layers, and a second electrode provided in common are layered in order corresponding to a plurality of subpixels constituting a display region, the first edge cover is provided so as to cover a circumferential end portion of each first electrode, and each inner circumferential end portion of the first edge cover is provided so as to protrude toward a central portion of the corresponding first electrode on a side separated from the first electrode in a thickness direction in a plan view.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. The organic EL display device includes, for example, a base substrate, a thin film transistor (hereinafter, also referred to as a “TFT”) layer provided on the base substrate, an organic EL element layer provided on the TFT layer, and a sealing film provided on the organic EL element layer. Here, an organic EL element includes a first electrode provided on the TFT layer, an organic EL layer provided as a light-emitting function layer on the first electrode, and a second electrode provided on the organic EL layer.

For example, PTL 1 describes that a projection is formed on a surface of a first electrode due to a protruding portion on a surface of a passivation film, thereby reflecting light generated from a light-emitting element layer to improve luminous efficiency.

### CITATION LIST

### Patent Literature

PTL 1: US 2017/0125740 A

### SUMMARY

### Technical Problem

Now, in the organic EL display device, for example, when the organic EL layer is formed on the first electrode by using a solution coating device such as an ink-jet or various coaters, solute components are likely to aggregate at the edge of an applied film due to a coffee ring effect in drying the applied film to be the organic EL layer. This makes a film thickness of the organic EL layer on a central portion of the first electrode relatively thinner, and makes a film thickness of the organic EL layer on an edge portion of the first electrode relatively thicker. In this case, since the film thickness of the organic EL layer varies in a subpixel, luminous unevenness occurs, thereby decreasing the luminous efficiency. Thus, there is room for improvement.

The disclosure has been made in view of the above, and an object thereof is to suppress luminous unevenness in a subpixel.

### Solution to Problem

In order to achieve the object, according to the disclosure, a display device includes a base substrate, a thin film transistor layer provided on the base substrate, and a light-emitting element layer provided on the thin film transistor layer and including a plurality of first electrodes, a first edge cover provided in common, a plurality of light-emitting function layers, and a second electrode provided in common corresponding to a plurality of subpixels constituting a display region, the plurality of first electrodes, the first edge cover, the plurality of light-emitting function layers, and the second electrode being layered in order, the first edge cover covering each of the circumferential end portions of the plurality of first electrodes, in which each inner circumferential end portion among a plurality of inner circumferential end portions of the first edge cover protrudes toward a central portion of a first electrode on a side separated from the corresponding first electrode in a thickness direction in a plan view.

### Advantageous Effects of Disclosure

According to the disclosure, it is possible to suppress luminous unevenness in a subpixel.

### BRIEF DESCRIPTION OF DRAWINGS

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is a plan view of a first electrode exposed from a first edge cover, which is a component of the organic EL display device according to the first embodiment of the disclosure.

FIG. 5 is an equivalent circuit diagram of a TFT layer, which is a component of the organic EL display device according to the first embodiment of the disclosure.

FIG. 6 is a cross-sectional view of an organic EL layer, which is a component of the organic EL display device according to the first embodiment of the disclosure.

FIG. 7 is a cross-sectional view of a display region of an organic EL display device according to a second embodiment of the disclosure, and is a view corresponding to FIG. 3.

FIG. 8 is a plan view of a first electrode exposed from a first edge cover, which is a component of the organic EL display device according to the second embodiment of the disclosure, and is a view corresponding to FIG. 4.

FIG. 9 is a cross-sectional view of a display region of an organic EL display device according to a third embodiment of the disclosure, and is a view corresponding to FIG. 3.

FIG. 10 is a schematic diagram illustrating a principle of formation of a fourth electrode, which is a component of the organic EL display device according to the third embodiment of the disclosure.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

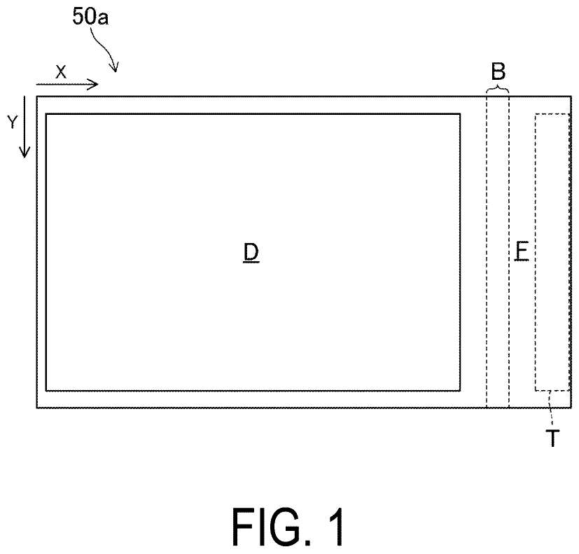

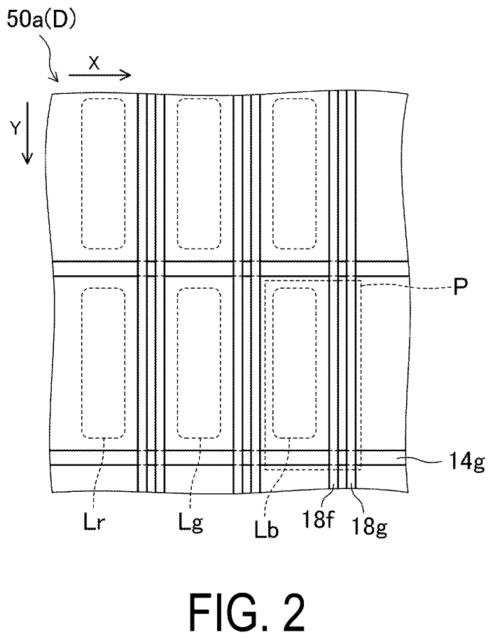

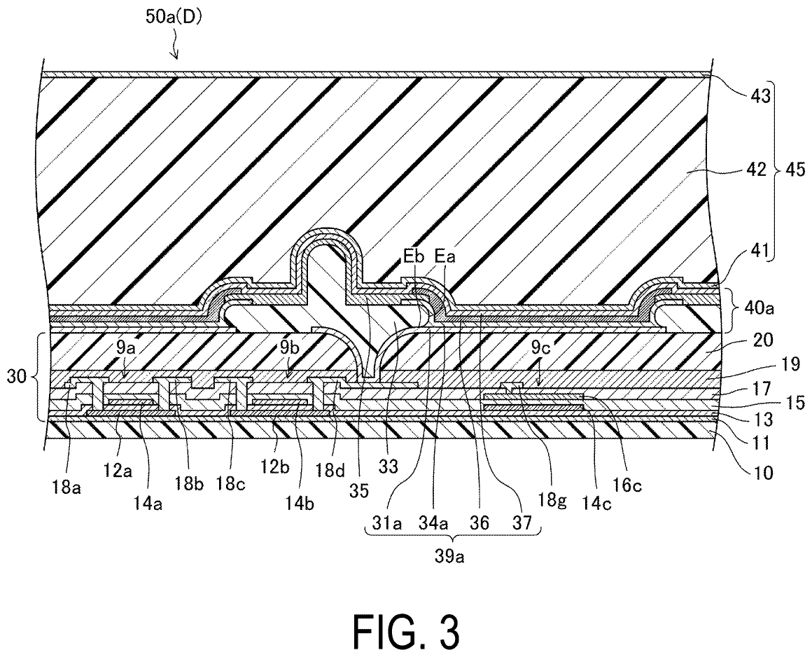

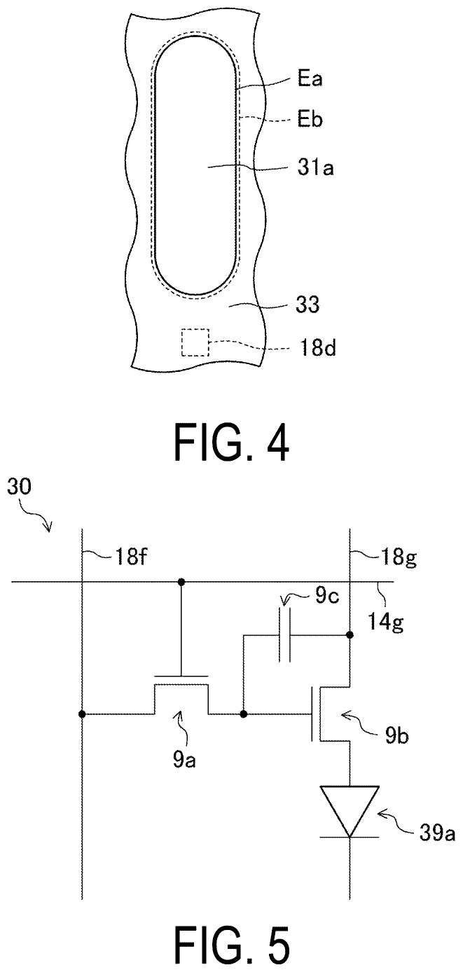

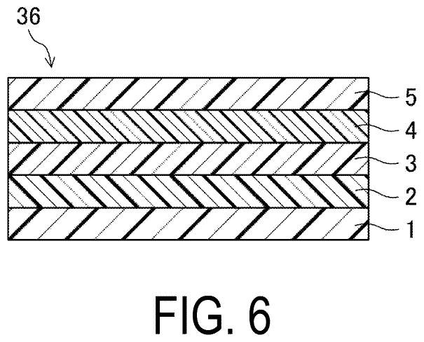

FIG. 1 to FIG. 6 illustrate a first embodiment of a display device according to the disclosure. Note that, in each of the following embodiments, an organic EL display device including an organic EL element layer is exemplified as a display device including a light-emitting element layer. Here, FIG. 1 is a plan view illustrating a schematic configuration of an organic EL display device 50a according to the present embodiment. FIG. 2 and FIG. 3 are a plan view and a cross-sectional view, respectively, of a display region D in the organic EL display device 50a. FIG. 4 is a plan view of a first electrode 31a exposed from a first edge cover 33, which is a component of the organic EL display device 50a. FIG. 5 is an equivalent circuit diagram of a TFT layer 30, which is a component of the organic EL display device 50a. FIG. 6 is a cross-sectional view of an organic EL layer 36, which is a component of the organic EL display device 50a.

As illustrated in FIG. 1, the organic EL display device 50a includes, for example, the display region D that is provided in a rectangular shape and in which an image is displayed, and a frame region F provided in a frame-like shape around the display region D. Note that, in the present embodiment, the display region D having the rectangular shape is exemplified, but the rectangular shape includes a substantially rectangular shape such as a shape whose sides are arc-shaped, a shape whose corners are arc-shaped, and a shape in which a part of a side has a notch.

As illustrated in FIG. 2, a plurality of subpixels P are arrayed in a matrix shape in the display region D. In the display region D, for example, a subpixel P including a red light-emitting region Lr for displaying a red color, a subpixel P including a green light-emitting region Lg for displaying a green color, and a subpixel P including a blue light-emitting region Lb for displaying a blue color are provided adjacent to one another, as illustrated in FIG. 2. Note that one pixel is configured by, for example, three adjacent subpixels P including the red light-emitting region Lr, the green light-emitting region Lg, and the blue light-emitting region Lb in the display region D.

A terminal portion T is provided extending in one direction (Y direction in the drawing) at a right end portion of the frame region F in FIG. 1. As illustrated in FIG. 1, between the display region D and the terminal portion T, that is, in the frame region F, a bending portion B, which is bendable, for example, by 180 degrees (in a U-shape) with the Y direction in the drawing as a bending axis, is provided extending in one direction (Y direction in the drawing) on a display region D side of the terminal portion T.

As illustrated in FIG. 3, the organic EL display device 50a includes a resin substrate 10 provided as a base substrate, the TFT layer 30 provided on the resin substrate 10, an organic EL element layer 40a provided on the TFT layer 30 as a light-emitting element layer, and a sealing film 45 provided on the organic EL element layer 40a.

The resin substrate 10 is formed of, for example, a polyimide resin or the like.

As illustrated in FIG. 3, the TFT layer 30 includes a base coat film 11 provided on the resin substrate 10, a plurality of first TFTs 9a, a plurality of second TFTs 9b, and a plurality of capacitors 9c, which are provided on the base coat film 11, and a protective insulating film 19 and a flattening film 20 that are provided in order on each first TFT 9a, each second TFT 9b, and each capacitor 9c. Here, as illustrated in FIG. 2, in the TFT layer 30, a plurality of gate lines 14g are provided to extend parallel to each other in an X direction in the figure. Additionally, as illustrated in FIG. 2, in the TFT layer 30, a plurality of source lines 18f are provided extending parallel to each other in a direction intersecting (orthogonal to) the plurality of gate lines 14g, that is, in the Y direction in the figure. In addition, as illustrated in FIG. 2, in the TFT layer 30, a plurality of power source lines 18g are provided to extend parallel to each other in the Y direction in the figure. Then, as illustrated in FIG. 2, each of the power source lines 18g is provided to be adjacent to each of the source lines 18f. Further, as illustrated in FIG. 5, in the TFT layer 30, the first TFT 9a, the second TFT 9b, and the capacitor 9c are provided in each of the subpixels P. Note that in the TFT layer 30, as illustrated in FIG. 3, on the resin substrate 10, the base coat film 11, a semiconductor film to serve as a semiconductor layer 12a and the like, which will be described later, a gate insulating film 13, a first metal film to serve as the gate line 14g and the like, a first interlayer insulating film 15, a second metal film to serve as an upper conductive layer 16c and the like, which will be described later, a second interlayer insulating film 17, a third metal film to serve as the source line 18f, the power source line 18g, and the like, the protective insulating film 19, and the flattening film 20 are sequentially layered.

Each of the base coat film 11, the gate insulating film 13, the first interlayer insulating film 15, the second interlayer insulating film 17, and the protective insulating film 19 is constituted by, for example, an inorganic insulating film that is a single-layer film or a layered film of silicon nitride, silicon oxide, silicon oxynitride, or the like.

The first TFT 9a is electrically connected to the corresponding gate line 14g and source line 18f in each of the subpixels P, as illustrated in FIG. 5. Here, as illustrated in FIG. 3, the first TFT 9a includes the semiconductor layer 12a provided on the base coat film 11, a gate electrode 14a provided on the semiconductor layer 12a with the gate insulating film 13 interposed therebetween, and a source electrode 18a and a drain electrode 18b that are provided on the second interlayer insulating film 17 so as to be separated from each other.

The semiconductor layer 12a is formed of, for example, a semiconductor film made of polysilicon such as low temperature polysilicon (LTPS), and includes a source region and a drain region that are defined so as to be separated from each other, and a channel region defined between the source region and the drain region.

The gate electrode 14a is provided overlapping with the channel region of the semiconductor layer 12a, and is configured to control conduction between the source region and the drain region of the semiconductor layer 12a. Here, the gate electrode 14a, similarly to the gate line 14g and the like, is formed of the first metal film.

Further, as illustrated in FIG. 3, the source electrode 18a and the drain electrode 18b are electrically connected to the source region and the drain region of the semiconductor layer 12a, respectively, through respective contact holes formed in the gate insulating film 13, the first interlayer insulating film 15, and the second interlayer insulating film 17. Here, the source electrode 18a and the drain electrode 18b, similarly to the source line 18f and the power source line 18g, are formed of the third metal film.

The second TFT 9b is electrically connected to the corresponding first TFT 9a and power source line 18g in each of the subpixels P as illustrated in FIG. 5. Here, as illustrated in FIG. 3, the second TFT 9b includes a semiconductor layer 12b provided on the base coat film 11, a gate electrode 14b provided on the semiconductor layer 12b with the gate insulating film 13 interposed therebetween, and a source electrode 18c and a drain electrode 18d that are provided on the second interlayer insulating film 17 so as to be separated from each other.

Similarly to the semiconductor layer 12a, the semiconductor layer 12b is formed of a semiconductor film made of, for example, polysilicon such as LTPS, and includes a source region and a drain region that are defined so as to be separated from each other, and a channel region defined between the source region and the drain region.

The gate electrode 14b is provided overlapping with the channel region of the semiconductor layer 12b, and is configured to control conduction between the source region and the drain region of the semiconductor layer 12b. Here, the gate electrode 14b, similarly to the gate line 14g and the like, is formed of the first metal film.

As illustrated in FIG. 3, the source electrode 18c and the drain electrode 18d are electrically connected to the source region and the drain region of the semiconductor layer 12b, respectively, through respective contact holes formed in the layered film of the gate insulating film 13, the first interlayer insulating film 15, and the second interlayer insulating film 17. Here, the source electrode 18c and the drain electrode 18d, similarly to the source line 18f and the power source line 18g, are formed of the third metal film.

Note that in the present embodiment, the semiconductor layers 12a and 12b formed of a semiconductor film made of polysilicon have been exemplified, but the semiconductor layers 12a and 12b may be formed of a semiconductor film made of an oxide semiconductor such as an In—Ga—Zn—O-based semiconductor. Furthermore, the TFT layer 30 may have a hybrid structure in which a TFT including a semiconductor layer formed of polysilicon and a TFT including a semiconductor layer formed of an oxide semiconductor are provided.

The capacitor 9c is electrically connected to the corresponding first TFT 9a and power source line 18g in each of the subpixels P as illustrated in FIG. 5. Here, as illustrated in FIG. 3, the capacitor 9c includes a lower conductive layer 14c formed of the first metal film, the upper conductive layer 16c provided and formed of the second metal film, and the first interlayer insulating film 15 provided between the lower conductive layer 14c and the upper conductive layer 16c. Note that, as illustrated in FIG. 3, the upper conductive layer 16c is electrically connected to the power source line 18g via a contact hole formed in the second interlayer insulating film 17.

The flattening film 20 has a flat surface in the display region D, and is formed of an organic resin material such as a polyimide resin, for example.

As illustrated in FIG. 3, the organic EL element layer 40a includes a plurality of first electrodes 31a, a first edge cover 33 provided in common, a plurality of third electrodes 34a, a second edge cover 35 provided in common, a plurality of organic EL layers 36, and a second electrode 37 provided in common, which are sequentially layered, corresponding to the plurality of subpixels P. Here, in each of the subpixels P, the first electrode 31a, the third electrode 34a, the organic EL layer 36, and the second electrode 37 constitute an organic EL element 39a, as illustrated in FIG. 3, and in the organic EL element layer 40a, a plurality of organic EL elements 39a are arranged in a matrix shape corresponding to the plurality of subpixels P.

As illustrated in FIG. 3, the first electrode 31a is electrically connected to the drain electrode 18d of the second TFT 9b of each subpixel P through a contact hole formed in the protective insulating film 19 and the flattening film 20. Here, the first electrode 31a is formed of, for example, a transparent conductive film such as Indium-Tin-Oxide (hereinafter, also referred to as “ITO”) and has optical transparency.

The first edge cover 33 is provided in a lattice pattern over the entire display region D, and covers circumferential end portions of the first electrodes 31a as illustrated in FIG. 3 and FIG. 4. The first edge cover 33 has light blocking properties and is made of a black organic resin material (e.g., polyimide resin, acrylic resin). Here, as illustrated in FIG. 3 and FIG. 4, each inner circumferential end portion of the first edge cover 33 is provided so as to protrude like eaves toward a central portion of the first electrode 31a on a side separated from the corresponding first electrode 31a in a thickness direction in a plan view. That is, a cross-sectional shape of each inner circumferential end portion of the first edge cover 33 on the first electrode 31a side is a reverse tapered shape, as illustrated in FIG. 3. Note that in the plan view in FIG. 4, a dashed line surrounding an inner circumferential end Ea of the first edge cover 33 indicated by a solid line indicates a lower end Eb of an inclined surface of the reverse tapered shape portion in the inner circumferential end portion of the first edge cover 33 that is in contact with the first electrode 31a.

The third electrode 34a has a function to inject holes into the organic EL layer 36, and is provided so as to cover the first electrode 31a exposed from the first edge cover 33, as illustrated in FIG. 3. Additionally, the third electrode 34a is preferably made of a material having a high work function to improve efficiency of hole injection into the organic EL layer 36. Here, the third electrode 34a is formed of, for example, a layered film in which a transparent conductive film made of ITO or the like, a metal film made of silver (Ag) or the like, and a transparent conductive film made of ITO or the like are layered in order, and has light reflectivity.

The second edge cover 35 is provided in a lattice pattern over the entire display region D, and covers circumferential end portions of the third electrodes 34a, as illustrated in FIG. 3. Here, the second edge cover 35 is constituted of an inorganic insulating film that is a single-layer film or a layered film of silicon nitride, silicon oxide, silicon oxynitride, or the like, for example.

The organic EL layer 36 is provided as a light-emitting function layer and includes a hole injection layer 1, a hole transport layer 2, a light-emitting layer 3, an electron transport layer 4, and an electron injection layer 5 that are sequentially layered on the third electrode 34a, as illustrated in FIG. 6. Here, the hole injection layer 1, the hole transport layer 2, the light-emitting layer 3, the electron transport layer 4, and the electron injection layer 5 are formed by applying and drying an aqueous solution in which each of constituent materials is dissolved, as will be described later.

The hole injection layer 1 is also referred to as an anode electrode buffer layer, and has a function to reduce an energy level difference between the third electrode 34a and the organic EL layer 36 and to improve efficiency of hole injection from the third electrode 34a to the organic EL layer 36. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function to improve efficiency of hole transport from the third electrode 34a to the organic EL layer 36. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where, when a voltage is applied by the third electrode 34a and the second electrode 37, a hole and an electron are injected from the third electrode 34a and the second electrode 37, respectively, and the hole and the electron are recombined. Here, the light-emitting layer 3 is made of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 has a function to reduce an energy level difference between the second electrode 37 and the organic EL layer 36 and to improve efficiency of electron injection from the second electrode 37 into the organic EL layer 36, and this function can lower a drive voltage of the organic EL element 39a. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 37 is provided covering each of the organic EL layers 36 and the second edge cover 35. Further, the second electrode 37 has a function to inject electrons into the organic EL layer 36. Further, the second electrode 37 is preferably made of a material having a low work function to improve efficiency of electron injection into the organic EL layer 36. Here, the second electrode 37 is formed of, for example, a transparent conductive film made of ITO or the like, and has optical transparency.

As illustrated in FIG. 3, the sealing film 45 is provided covering the second electrode 37, includes a first inorganic sealing film 41, an organic sealing film 42, and a second inorganic sealing film 43 that are sequentially layered on the second electrode 37, and has a function to protect the organic EL layer 36 of the organic EL element 39a from moisture, oxygen, and the like. Here, the first inorganic sealing film 41 and the second inorganic sealing film 43 include, for example, an inorganic insulating film such as a silicon nitride film, a silicon oxide film, and a silicon oxynitride film. Additionally, the organic sealing film 42 is made of, for example, an organic resin material such as an acrylic resin, an epoxy resin, a silicone resin, a polyurea resin, a parylene resin, a polyimide resin, and a polyamide resin.

In the organic EL display device 50a described above, in each of the subpixels P, a gate signal is input to the first TFT 9a through the gate line 14g to turn on the first TFT 9a, a data signal is written in the gate electrode 14b of the second TFT 9b and the capacitor 9c through the source line 18f, and a current from the power source line 18g corresponding to a gate voltage of the second TFT 9b is supplied to the organic EL layer 36 of the organic EL element 39a, whereby the light-emitting layer 3 of the organic EL layer 36 emits light to display an image. Further, in the organic EL display device 50a, even when the first TFT 9a is turned off, the gate voltage of the second TFT 9b is held by the capacitor 9c, and thus, light emission by the light-emitting layer 3 is maintained until a gate signal of the next frame is input.

Note that in the present embodiment, the organic EL display device 50a including the third electrodes 34a and the second edge cover 35 is exemplified, but the third electrodes 34a and the second edge cover 35 may be omitted.

In the present embodiment, although the organic EL display device 50a of a top-emitting type in which the first electrodes 31a and the second electrode 37 have optical transparency and the third electrodes 34a have light reflectivity has been exemplified, the organic EL display device 50a may be a bottom-emitting type in which the first electrodes 31a and the third electrodes 34a have optical transparency and the second electrode 37 has light reflectivity.

Next, a method of manufacturing the organic EL display device 50a according to the present embodiment will be described. Here, the method of manufacturing the organic EL display device 50a according to the present embodiment includes a TFT layer forming step, an organic EL element layer forming step, and a sealing film forming step.

### TFT Layer Forming Step

First, a silicon nitride film (having a thickness of about 50 nm) and a silicon oxide film (having a thickness of about 250 nm) are sequentially formed on the resin substrate 10 formed on a glass substrate by, for example, plasma Chemical Vapor Deposition (CVD), to form the base coat film 11.

Subsequently, an amorphous silicon film (having a thickness of about 50 nm) is formed, for example, by plasma CVD on the substrate surface on which the base coat film 11 is formed, the amorphous silicon film is crystallized by laser annealing or the like to form the semiconductor film made of polysilicon, and then the semiconductor film is patterned to form the semiconductor layers 12a and 12b, and the like.

After that, a silicon oxide film (having a thickness of about 100 nm) is formed, for example, by plasma CVD on the substrate surface on which the semiconductor layer 12a and the like are formed, to form the gate insulating film 13.

Further, after forming a first metal film such as a molybdenum film (having a thickness of about 200 nm), for example, by sputtering on the substrate surface on which the gate insulating film 13 is formed, the first metal film is patterned to form the gate electrodes 14a and 14b, and the like.

Subsequently, by doping the semiconductor layers 12a and 12b with impurity ions by using the gate electrodes 14a and 14b as a mask, the semiconductor layers 12a and 12b are partially made conductive, and a source region, a drain region, and a channel region are formed in each of the semiconductor layers 12a and 12b.

After that, a silicon nitride film (having a thickness of about 150 nm) and a silicon oxide film (having a thickness of about 100 nm) are sequentially formed, for example, by plasma CVD, on the substrate surface on which the semiconductor layers 12a and 12b are partially made conductive, to form the first interlayer insulating film 15.

Furthermore, after forming a second metal film such as a molybdenum film (having a thickness of approximately 200 nm) or the like by, for example, sputtering on the substrate surface on which the first interlayer insulating film 15 is formed, the second metal film is patterned to form the upper conductive layer 16c and the like.

After that, a silicon oxide film (about 300 nm in thickness) and a silicon nitride film (about 150 nm in thickness) are formed in order, by, for example, plasma CVD, on the substrate surface on which the upper conductive layer 16c and the like are formed, thereby forming the second interlayer insulating film 17.

Subsequently, on the substrate surface on which the second interlayer insulating film 17 is formed, the first gate insulating film 13, the first interlayer insulating film 15, and the second interlayer insulating film 17 are appropriately patterned to form contact holes.

After that, a titanium film (having a thickness of approximately 50 nm), an aluminum film (having a thickness of approximately 400 nm), a titanium film (having a thickness of approximately 100 nm), and the like are sequentially formed, for example, by sputtering, on the substrate surface in which the above-described contact holes are formed to form a third metal film, and then, the third metal film is patterned to form the source electrodes 18a and 18c, the drain electrodes 18b and 18d, and the like.

Further, a silicon oxide film (having a thickness of about 250 nm) is formed on the substrate surface on which the source electrode 18a and the like are formed, for example, by plasma CVD to form the protective insulating film 19.

Subsequently, an acrylic photosensitive resin film (having a thickness of about 2 μm) is applied to the substrate surface on which the protective insulating film 19 is formed, for example, by a spin coating method or a slit coating method, and then, pre-baking, exposing, developing, and post-baking are performed on the applied film to form the flattening film 20 including a contact hole.

Finally, the protective insulating film 19 exposed from the contact hole of the flattening film 20 is removed so that the contact hole reaches the drain electrode 18d of the second TFT 9b.

As described above, the TFT layer 30 can be formed.

### Organic EL Element Layer Forming Step

First, a transparent conductive film such as an ITO film (having a thickness of about 100 nm) is formed, for example, by sputtering on the substrate surface on which the TFT layer 30 is formed in the TFT layer forming step described above, and then the transparent conductive film is patterned to form the first electrodes 31a.

Subsequently, an acrylic negative type photosensitive resin film (having a thickness of about 2 μm) is applied to the substrate surface on which the first electrodes 31a are formed, for example, by a spin coating method or a slit coating method, and then pre-baking, exposing, developing, and post-baking are performed on the applied film to form the first edge cover 33.

After that, a transparent conductive film such as an ITO film (having a thickness of approximately 40 nm), a metal film such as an Ag film (having a thickness of approximately 20 nm), and a transparent conductive film such as an ITO film (having a thickness of approximately 40 nm) are sequentially formed, for example, by sputtering on the substrate surface on which the first edge cover 33 is formed, and then, a layered film thereof is patterned to form the third electrodes 34a.

Further, an inorganic insulating film such as a silicon nitride film (having a thickness of about 250 nm) is formed on the substrate surface on which the third electrodes 34a and the like are formed, for example, by plasma CVD, and then the inorganic insulating film is patterned to form the second edge cover 35.

Subsequently, the hole injection layer 1, the hole transport layer 2, the light-emitting layer 3, the electron transport layer 4, and the electron injection layer 5 are sequentially formed on the substrate surface on which the second edge cover 35 is formed by repeating application and drying of an aqueous solution in which predetermined constituent materials are dissolved by, for example, an ink-jet method, thereby forming the organic EL layer 36.

Finally, on the substrate surface on which the organic EL layer 36 is formed, a transparent conductive film such as an ITO film (having a thickness of about 100 nm) is formed by sputtering by using a mask to form the second electrode 37.

As described above, the organic EL element layer 40a can be formed.

### Sealing Film Forming Step

First, an inorganic insulating film such as a silicon nitride film, a silicon oxide film, or a silicon oxynitride film is formed by plasma CVD by using a mask on the substrate surface on which the organic EL element layer 40a is formed in the organic EL element layer forming step described above, thereby forming the first inorganic sealing film 41.

Next, on the substrate surface on which the first inorganic sealing film 41 is formed, a film made of an organic resin material such as acrylic resin is formed by, for example, using an ink-jet method to form the organic sealing film 42.

Further, an inorganic insulating film such as a silicon nitride film, a silicon oxide film, or a silicon oxynitride film is formed by plasma CVD on the substrate on which the organic sealing film 42 is formed, by using a mask to form the second inorganic sealing film 43, thereby forming the sealing film 45.

Finally, after a protective sheet (not illustrated) is attached to the substrate surface on which the sealing film 45 is formed, the glass substrate is peeled off from the lower face of the resin substrate 10 by irradiation with laser light from the glass substrate side of the resin substrate 10, and further a protective sheet (not illustrated) is attached to the lower face of the resin substrate 10 from which the glass substrate has been peeled off.

The organic EL display device 50a of the present embodiment can be manufactured as described above.

As described above, according to the organic EL display device 50a of the present embodiment, in each subpixel P, the inner circumferential end portion of the first edge cover 33 is provided so as to protrude like eaves toward the central portion of the first electrode 31a on the side separated from the first electrode 31a in the thickness direction in a plan view, so that the cross-sectional shape of each inner circumferential end portion of the first edge cover 33 on the first electrode 31a side is the reverse tapered shape. Therefore, the second electrode 37 formed by sputtering is not formed by entering the reverse tapered shape portion of each inner circumferential end portion of the first edge cover 33. Then, since an electrical field by the second electrode 37 is not applied to the reverse tapered shape portion of each inner circumferential end portion of the first edge cover 33, that portion does not emit light and becomes a buffer region that does not contribute to image display. This suppresses luminous unevenness in each inner circumferential end portion of the first edge cover 33, thereby suppressing luminous unevenness in the subpixel P.

In addition, according to the organic EL display device 50a of the present embodiment, since the first edge cover 33 is made of a black organic resin material and has light blocking properties, it is possible to suppress mixing of emitted colors due to unnecessary reflection, stray light, scattering, and the like when each of the organic EL elements 39a emits light, thereby improving display quality.

### Second Embodiment

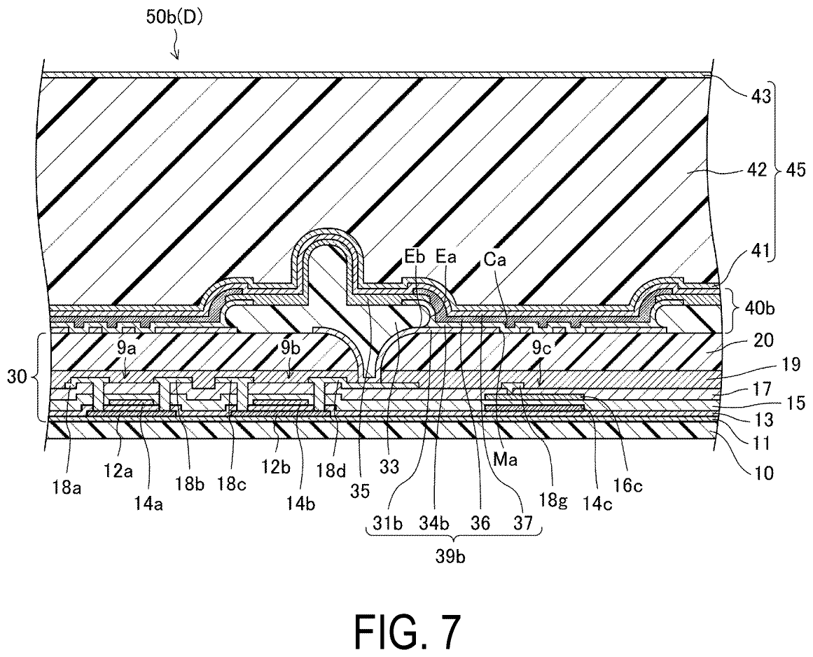

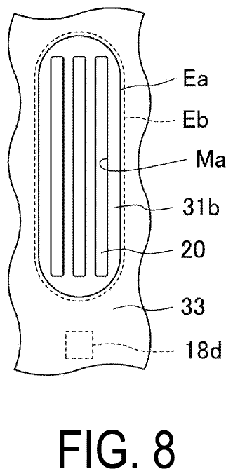

FIG. 7 and FIG. 8 illustrate a second embodiment of an organic EL display device according to the disclosure. Here, FIG. 7 is a cross-sectional view of a display region D of an organic EL display device 50b according to the present embodiment, and is a view corresponding to FIG. 3 described in the first embodiment. FIG. 8 is a plan view of a first electrode 31b exposed from a first edge cover 33, which is a component of the organic EL display device 50b, and is a view corresponding to FIG. 4 described in the first embodiment. In the following embodiments, parts identical to those in FIG. 1 to FIG. 6 are designated by the same reference signs, and detailed descriptions thereof will be omitted.

In the first embodiment, the organic EL display device 50a in which surfaces of the third electrodes 34a exposed from the second edge cover 35 are provided smoothly is exemplified. However, in the present embodiment, the organic EL display device 50b in which surfaces of third electrodes 34b exposed from the second edge cover 35 are provided unevenly will be exemplified.

The organic EL display device 50b, similarly to the organic EL display device 50a of the first embodiment, includes, for example, the display region D provided in a rectangular shape for displaying images and a frame region F provided in a frame-like shape around the display region D. As illustrated in FIG. 7, the organic EL display device 50b includes a resin substrate 10 provided as a base substrate, a TFT layer 30 provided on the resin substrate 10, an organic EL element layer 40b provided on the TFT layer 30 as a light-emitting element layer, and a sealing film 45 provided on the organic EL element layer 40b.

As illustrated in FIG. 7, the organic EL element layer 40b includes a plurality of first electrodes 31b, the first edge cover 33 provided in common, the plurality of third electrodes 34b, the second edge cover 35 provided in common, a plurality of organic EL layers 36, and a second electrode 37 provided in common, which are sequentially layered, corresponding to a plurality of subpixels P. Here, in each of the subpixels P, the first electrode 31b, the third electrode 34b, the organic EL layer 36, and the second electrode 37 constitute an organic EL element 39b, as illustrated in FIG. 7, and in the organic EL element layer 40b, a plurality of organic EL elements 39b are arranged in a matrix shape corresponding to the plurality of subpixels P.

As illustrated in FIG. 7, the first electrode 31b is electrically connected to a drain electrode 18d of a second TFT 9b of each subpixel P through a contact hole formed in a protective insulating film 19 and a flattening film 20. Here, the first electrode 31b is formed of, for example, a transparent conductive film made of ITO or the like, and has optical transparency. Further, a circumferential end portion of the first electrode 31b is covered with the first edge cover 33, and the first electrode 31b exposed from the first edge cover 33, as illustrated in FIG. 7 in a cross-sectional view, has a plurality of linear openings Ma that pass through the first electrode 31b to expose the flattening film 20 of the TFT layer 30 and, as illustrated in FIG. 8 in a plan view, extend parallel to each other. Note that in the present embodiment, the openings Ma that pass through the first electrode 31b are exemplified, but the openings Ma may be provided on the third electrode 34b side without passing through the first electrode 31b. In addition, in the present embodiment, the first electrode 31b with the plurality of openings Ma having a linear shape is exemplified, but the shape of the plurality of openings Ma may be a dot shape or a combination of a linear shape and a dot shape.

The third electrode 34b has a function to inject holes into the organic EL layer 36, and is provided so as to cover the first electrode 31b exposed from the first edge cover 33, as illustrated in FIG. 7. Additionally, the third electrode 34b is preferably made of a material having a high work function to improve efficiency of hole injection into the organic EL layer 36. Here, the third electrode 34b is formed of, for example, a layered film in which a transparent conductive film made of ITO or the like, a metal film made of silver (Ag) or the like, and a transparent conductive film made of ITO or the like are layered in order, and has light reflectivity. Additionally, as illustrated in FIG. 7, a plurality of recessed portions Ca are arranged on a surface of the third electrode 34b in correspondence with the plurality of openings Ma in the first electrode 31b. Note that as illustrated in FIG. 7, a circumferential end portion of the third electrode 34b is covered with the second edge cover 35.

The organic EL display device 50b described above, similarly to the organic EL display device 50a of the first embodiment, is flexible, and is configured to display an image by causing a light-emitting layer 3 of the organic EL layer 36 to appropriately emit light via a first TFT 9a and the second TFT 9b in each subpixel P.

Note that in the present embodiment, although the organic EL display device 50b of a top-emitting type in which the first electrodes 31b and the second electrode 37 have optical transparency and the third electrodes 34b have light reflectivity has been exemplified, the organic EL display device 50b may be a bottom-emitting type in which the first electrodes 31b and the third electrodes 34b have optical transparency and the second electrode 37 has light reflectivity.

The organic EL display device 50b of the present embodiment can be manufactured by changing the pattern shape of the first electrodes 31a in the organic EL element layer forming step in the method of manufacturing the organic EL display device 50a of the first embodiment.

As described above, according to the organic EL display device 50b of the present embodiment, in each subpixel P, an inner circumferential end portion of the first edge cover 33 is provided so as to protrude like eaves toward a central portion of the first electrode 31b on a side separated from the first electrode 31b in a thickness direction in a plan view, so that a cross-sectional shape of each inner circumferential end portion of the first edge cover 33 on the first electrode 31b side is a reverse tapered shape. Therefore, the second electrode 37 formed by sputtering is not formed by entering the reverse tapered shape portion of each inner circumferential end portion of the first edge cover 33. Then, since an electrical field by the second electrode 37 is not applied to the reverse tapered shape portion of each inner circumferential end portion of the first edge cover 33, that portion does not emit light and becomes a buffer region that does not contribute to image display. This suppresses luminous unevenness in each inner circumferential end portion of the first edge cover 33, thereby suppressing luminous unevenness in the subpixel P.

In addition, according to the organic EL display device 50b of the present embodiment, since the first edge cover 33 is made of a black organic resin material and has light blocking properties, it is possible to suppress mixing of emitted colors due to unnecessary reflection, stray light, scattering, and the like when each of the organic EL elements 39b emits light, thereby improving display quality.

Further, according to the organic EL display device 50b of the present embodiment, each first electrode 31b exposed from the first edge cover 33 is provided with the plurality of openings Ma extending side by side in a linear shape so as to pass through each of the first electrode 31b and expose the flattening film 20 of the TFT layer 30, and the plurality of recessed portions Ca corresponding to the plurality of openings Ma are provided on the surface of each third electrode 34b. Here, respective solute components of the organic EL layer 36, which are formed on the surface of each third electrode 34b by application and drying and which are generally likely to flow to a periphery due to a coffee ring effect, are less likely to flow to the periphery due to an increase in surface area by the plurality of recessed portions Ca formed on the surface of each third electrode 34b. This reduces a difference in film thickness of the organic EL layer 36 formed on the surface of each third electrode 34b by application and drying, thereby suppressing a variation in film thickness of the organic EL layer 36 in the subpixel P. Furthermore, since the variation in film thickness of the organic EL layer 36 in each subpixel P can be suppressed, luminous unevenness by the organic EL element 39b of the subpixel P can be further suppressed, thereby suppressing a decrease in luminous efficiency.

In addition, according to the organic EL display device 50b of the present embodiment, the plurality of recessed portions Ca are provided on the surface of the third electrode 34b having light reflectivity, thereby improving luminance when the organic EL layer 36 emits light in each subpixel P.

### Third Embodiment

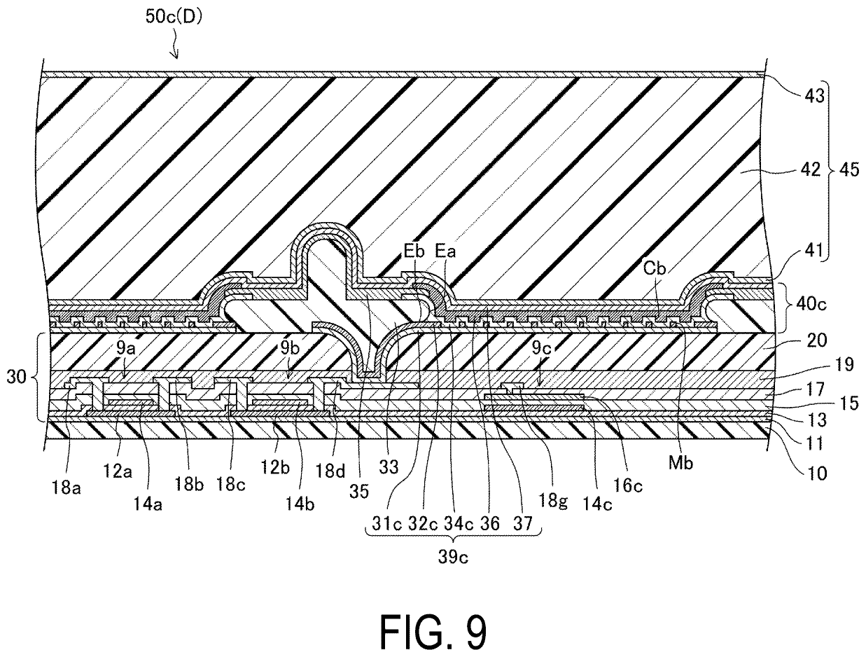

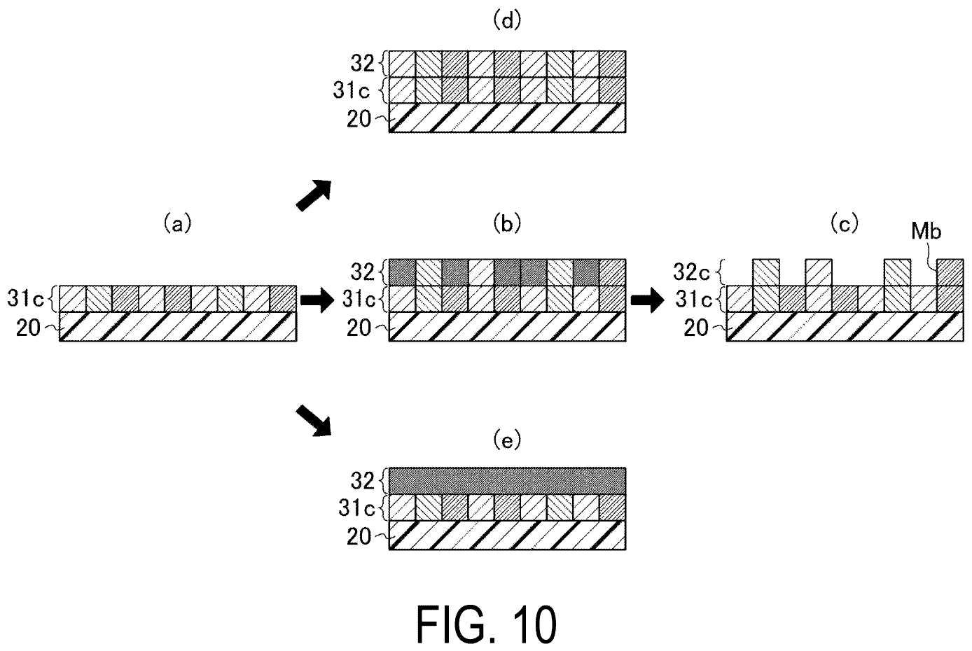

FIG. 9 and FIG. 10 illustrate a third embodiment of a display device according to the disclosure. Here, FIG. 9 is a cross-sectional view of a display region D of an organic EL display device 50c according to the present embodiment, and is a view corresponding to FIG. 3 described in the first embodiment. FIG. 10 is a schematic diagram illustrating a principle of formation of a fourth electrode 32c, which is a component of the organic EL display device 50c.

In the second embodiment, the organic EL display device 50b in which the surface of the third electrode 34b exposed from the second edge cover 35 has a relatively rough uneven structure is exemplified. In the present embodiment, the organic EL display device 50c in which a surface of a third electrode 34c exposed from a second edge cover 35 has a relatively fine uneven structure is exemplified.

The organic EL display device 50c, similarly to the organic EL display device 50a of the first embodiment, includes, for example, the display region D provided in a rectangular shape for displaying images and a frame region F provided in a frame-like shape around the display region D. As illustrated in FIG. 9, the organic EL display device 50c includes a resin substrate 10 provided as a base substrate, a TFT layer 30 provided on the resin substrate 10, an organic EL element layer 40c provided on the TFT layer 30 as a light-emitting element layer, and a sealing film 45 provided on the organic EL element layer 40c.

As illustrated in FIG. 9, the organic EL element layer 40c includes a plurality of first electrodes 31c, a plurality of fourth electrodes 32c, a first edge cover 33 provided in common, a plurality of third electrodes 34c, the second edge cover 35 provided in common, a plurality of organic EL layers 36, and a second electrode 37 provided in common, which are sequentially layered, corresponding to a plurality of subpixels P. Here, in each of the subpixels P, the first electrode 31c, the fourth electrode 32c, the third electrode 34c, the organic EL layer 36, and the second electrode 37 constitute an organic EL element 39c, as illustrated in FIG. 9, and in the organic EL element layer 40c, a plurality of organic EL elements 39c are arranged in a matrix shape corresponding to the plurality of subpixels P.

As illustrated in FIG. 9, the first electrode 31c is electrically connected to a drain electrode 18d of a second TFT 9b of each subpixel P through a contact hole formed in a protective insulating film 19 and a flattening film 20. Here, the first electrode 31c is formed of, for example, a transparent conductive film made of ITO or the like, and has optical transparency. The first electrode 31c is composed of crystal grains of the transparent conductive film having a predetermined crystal orientation.

As illustrated in FIG. 9, the fourth electrode 32c is provided on the first electrode 31c so that a circumferential end portion of the fourth electrode 32c overlaps a circumferential end portion of the first electrode 31c. Here, the fourth electrode 32c, similarly to the first electrode 31c, is formed of, for example, a transparent conductive film made of ITO or the like, and has optical transparency. The fourth electrode 32c is composed of crystal grains of a transparent conductive film having a predetermined crystal orientation, and the crystal orientation of the crystal grains of the fourth electrode 32c is the same as the crystal orientation of the crystal grains of each first electrode 31c that is continuous with the fourth electrode 32c along a thickness direction of the resin substrate 10. In addition, as illustrated in FIG. 9, the circumferential end portion of the fourth electrode 32c is covered with the first edge cover 33, and the fourth electrode 32c exposed from the first edge cover 33 has a plurality of openings Mb randomly provided in a dot shape so as to pass through the fourth electrode 32c and expose the first electrode 31c, as illustrated in FIG. 9. Here, a size of the opening Mb is, for example, about 100 nm in diameter and about 50 nm in depth. As will be described later, the openings Mb in the fourth electrode 32c are provided by removing amorphous portions and microcrystalline portions of a transparent conductive film that serves as the fourth electrode 32c. Note that in the present embodiment, the openings Mb that pass through the fourth electrode 32c are exemplified, but the openings Mb may be provided on the third electrode 34c side without passing through the fourth electrode 32c.

The third electrode 34c has a function to inject holes into the organic EL layer 36, and is provided so as to cover the fourth electrode 32c exposed from the first edge cover 33, as illustrated in FIG. 9. Additionally, the third electrode 34c is preferably made of a material having a high work function to improve efficiency of hole injection into the organic EL layer 36. Here, the third electrode 34c is formed of, for example, a layered film in which a transparent conductive film made of ITO or the like, a metal film made of silver (Ag) or the like, and a transparent conductive film made of ITO or the like are layered in order, and has light reflectivity. In addition, as illustrated in FIG. 9, a surface of the third electrode 34c has a plurality of recessed portions Cb corresponding to the plurality of openings Mb in the fourth electrode 32c, so that the surface of the third electrode 34c has a nanoscale uneven structure caused by the openings Mb in the fourth electrode 32c. Note that as illustrated in FIG. 9, a circumferential end portion of the third electrode 34c is covered with the second edge cover 35.

The organic EL display device 50c described above, similarly to the organic EL display device 50a of the first embodiment, is flexible, and is configured to display an image by causing a light-emitting layer 3 of the organic EL layer 36 to appropriately emit light via a first TFT 9a and the second TFT 9b in each subpixel P.

The organic EL display device 50c of the present embodiment can be manufactured by changing the organic EL element layer forming step in the method of manufacturing the organic EL display device 50a of the first embodiment as follows.

### Organic EL Element Layer Forming Step

First, a transparent conductive film such as an ITO film (having a thickness of about 50 nm) is formed, for example, by sputtering on a substrate surface on which the TFT layer 30 is formed in the TFT layer forming step of the first embodiment, and then the transparent conductive film is patterned to form the first electrodes 31c. To be specific, when forming the first electrodes 31c, for example, an amorphous ITO film is formed by sputtering using argon gas, oxygen gas, and water vapor as sputtering gas, and then the amorphous ITO film is patterned and then crystallized by annealing, so that the first electrodes 31c are formed of a crystalline ITO film (see FIG. 10 (a)). Note that in FIG. 10 (a), three types of hatching are used to schematically illustrate that the first electrode 31c is formed of three types of crystal grains having different crystal orientations.

Subsequently, a transparent conductive film such as an ITO film (having a thickness of about 50 nm) is formed, for example, by sputtering on the substrate surface on which the first electrodes 31c are formed, and then the transparent conductive film is patterned to form the fourth electrodes 32c. To be specific, when forming the fourth electrodes 32c, for example, an ITO film 32 including crystalline portions, amorphous portions, and microcrystalline portions is formed by sputtering using argon gas, oxygen gas, and water vapor as sputtering gas, and then the amorphous portions and the microcrystalline portions of the ITO film 32 (dot portions in FIG. 10 (b)) are removed by wet etching using oxalic acid or the like, thereby forming the fourth electrodes 32c having the openings Mb (see FIG. 10 (b) and FIG. 10 (c)). Here, when a flow rate of water vapor in the sputtering gas is low, as illustrated in FIG. 10 (d), the ITO film 32 composed of crystal grains (hatched portions in the figure) having the same crystal orientations as the crystal grains of the first electrode 31c is formed so as to be aligned with (the crystal grains of) the first electrode 31c, that is, so that the crystal orientations of the crystal grains are continuous in the thickness direction of the resin substrate 10. When the flow rate of water vapor in the sputtering gas is high, as illustrated in FIG. 10 (e), the ITO film 32 including only the amorphous portions and the microcrystalline portions (a dot portion in the figure) is formed. When the flow rate of water vapor in the sputtering gas is appropriate, as illustrated in FIG. 10 (b), the ITO film 32 is formed in which amorphous portions and microcrystalline portions (dotted portions in the figure) are randomly arranged between crystal grains having the same crystal orientations as the crystal grains of the first electrode 31c (hatched portions in the figure).

Furthermore, an acrylic photosensitive resin film (having a thickness of about 2 μm) is applied to the substrate surface on which the fourth electrodes 32c are formed, for example, by a spin coating method or a slit coating method, and then pre-baking, exposing, developing, and post-baking are performed on the applied film to form the first edge cover 33.

After that, a transparent conductive film such as an ITO film (having a thickness of approximately 40 nm), a metal film such as an Ag film (having a thickness of approximately 20 nm), and a transparent conductive film such as an ITO film (having a thickness of approximately 40 nm) are sequentially formed, for example, by sputtering on the substrate surface on which the first edge cover 33 is formed, and then, a layered film thereof is patterned to form the third electrodes 34c having the recessed portions Cb.

Further, an inorganic insulating film such as a silicon nitride film (having a thickness of about 250 nm) is formed on the substrate surface on which the third electrodes 34c are formed, for example, by plasma CVD, and then the inorganic insulating film is patterned to form the second edge cover 35.

Subsequently, a hole injection layer 1, a hole transport layer 2, a light-emitting layer 3, an electron transport layer 4, and an electron injection layer 5 each having a film thickness of tens of nanometers to hundreds of nanometers are sequentially formed on the substrate surface on which the second edge cover 35 is formed by repeating application and drying of an aqueous solution in which predetermined constituent materials are dissolved by, for example, an ink-jet method, thereby forming the organic EL layer 36.

Finally, on the substrate surface on which the organic EL layer 36 is formed, a transparent conductive film such as an ITO film (having a thickness of about 100 nm) is formed by sputtering by using a mask to form the second electrode 37.

As described above, the organic EL element layer 40c can be formed. Thereafter, the sealing film forming step is performed in the same manner as in the first embodiment, whereby the organic EL display device 50c of the present embodiment can be manufactured.

As described above, according to the organic EL display device 50c of the present embodiment, in each subpixel P, an inner circumferential end portion of the first edge cover 33 is provided so as to protrude like eaves toward a central portion of the first electrode 31c on a side separated from the first electrode 31c in a thickness direction in a plan view, so that a cross-sectional shape of each inner circumferential end portion of the first edge cover 33 on the first electrode 31c side is a reverse tapered shape. Therefore, the second electrode 37 formed by sputtering is not formed by entering the reverse tapered shape portion of each inner circumferential end portion of the first edge cover 33. Then, since an electrical field by the second electrode 37 is not applied to the reverse tapered shape portion of each inner circumferential end portion of the first edge cover 33, that portion does not emit light and becomes a buffer region that does not contribute to image display. This suppresses luminous unevenness in each inner circumferential end portion of the first edge cover 33, thereby suppressing luminous unevenness in the subpixel P.

Further, according to the organic EL display device 50c of the present embodiment, each fourth electrode 32c exposed from the first edge cover 33 is provided with the plurality of openings Mb in a point shape that pass through each fourth electrode 32c and expose each first electrode 31c, and the surface of each third electrode 34c is provided with the plurality of recessed portions Cb corresponding to the plurality of openings Mb. Here, respective solute components of the organic EL layer 36, which are formed on the surface of each third electrode 34c by application and drying and which are generally likely to flow to a periphery due to a coffee ring effect, are less likely to flow to the periphery due to an increase in surface area by the plurality of recessed portions Cb formed on the surface of each third electrode 34c. This reduces a difference in film thickness of the organic EL layer 36 formed on the surface of each third electrode 34c by application and drying, thereby suppressing a variation in film thickness of the organic EL layer 36 in the subpixel P. Furthermore, since the variation in film thickness of the organic EL layer 36 in each subpixel P can be suppressed, luminous unevenness by the organic EL element 39c of the subpixel P can be suppressed, thereby suppressing a decrease in luminous efficiency.

In addition, according to the organic EL display device 50c of the present embodiment, the openings Mb in each fourth electrode 32c are formed at the crystal level by removing the amorphous portions and the microcrystalline portions of the transparent conductive film 32 rather than by photolithography, so that a nanoscale uneven structure with the plurality of recessed portions Cb can be formed on the surface of each third electrode 34c. This makes it possible to reliably suppress variations in the organic EL layer 36 formed by layering the hole injection layer 1, the hole transport layer 2, the light-emitting layer 3, the electron transport layer 4, and the electron injection layer 5, each having a film thickness of tens of nanometers to hundreds of nanometers.

In addition, according to the organic EL display device 50c of the present embodiment, the uneven structure due to the plurality of recessed portions Cb formed on the surface of the third electrode 34c is on a nanoscale and unevenness is small. Therefore, even when the film thicknesses of the hole injection layer 1, the hole transport layer 2, the light-emitting layer 3, the electron transport layer 4, and the electron injection layer 5 are each thin, it is possible to suppress a short circuit between the first electrode 31c and the second electrode 37 in each subpixel P.

### Other Embodiments

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

Although the organic EL display device in which the electrode of the TFT connected to the first electrode serves as the drain electrode has been exemplified in each of the embodiments described above, the disclosure is also applicable to an organic EL display device in which the electrode of the TFT connected to the first electrode is referred to as the source electrode.

In each of the embodiments described above, the organic EL display device has been exemplified as the display device. The disclosure can also be applied to a display device including a plurality of light-emitting elements to be driven by a current, for example, to a display device including quantum dot light-emitting diodes (QLEDs), each of which is a light-emitting element using a quantum dot-containing layer.

### INDUSTRIAL APPLICABILITY

As described above, the disclosure is useful for a flexible display device.

1. A display device comprising:
a base substrate;
a thin film transistor layer provided on the base substrate; and
a light-emitting element layer provided on the thin film transistor layer and including a plurality of first electrodes, a first edge cover provided in common, a plurality of light-emitting function layers, and a second electrode provided in common corresponding to a plurality of subpixels constituting a display region, the plurality of first electrodes, the first edge cover, the plurality of light-emitting function layers, and the second electrode being layered in order, the first edge cover covering each of the circumferential end portions of the plurality of first electrodes,
wherein each inner circumferential end portion among a plurality of inner circumferential end portions of the first edge cover protrudes toward a central portion of a first electrode on a side separated from the corresponding first electrode in a thickness direction in a plan view,
a plurality of third electrodes and a second edge cover provided in common corresponding to the plurality of subpixels are provided between the first edge cover and the plurality of light-emitting function layers in order from a first edge cover side, and
the second edge cover covers circumferential end portions of the plurality of third electrodes.

2. The display device according to claim 1,
wherein the first edge cover has light blocking properties.

3. The display device according to claim 2,
wherein the first edge cover is made of a black organic resin material.

4. (canceled)

5. The display device according to claim 1,
wherein each of the plurality of first electrodes exposed from the first edge cover is provided with a plurality of openings passing through each of the plurality of first electrodes, and
a surface of each of the plurality of third electrodes is provided with a plurality of recessed portions corresponding to the plurality of openings.

6. The display device according to claim 5,
wherein the plurality of first electrodes and the second electrode have optical transparency, and
the plurality of third electrodes have light reflectivity.

7. The display device according to claim 4,
wherein a plurality of fourth electrodes corresponding to the plurality of subpixels are provided between the plurality of first electrodes and the first edge cover,
each of the plurality of fourth electrodes exposed from the first edge cover is provided with a plurality of openings passing through each of the plurality of fourth electrodes, and
a surface of each of the plurality of third electrodes is provided with a plurality of recessed portions corresponding to the plurality of openings.

8. The display device according to claim 7,
wherein the plurality of first electrodes, the second electrode, and the plurality of fourth electrodes have optical transparency, and
the third electrodes have light reflectivity.

9. The display device according to claim 1,
wherein the first edge cover is made of an organic resin material, and
the second edge cover is formed of an inorganic insulating film.

10. The display device according to claim 1, the display device comprising:
a sealing film provided on the light-emitting element layer.

11. The display device according to claim 1,
wherein each of the plurality of light-emitting function layers is an organic electroluminescence layer.
